(19) United States
(12) Patent Application Publication
(10) Pub. No.: US 2025/0149513 A1
(43) Pub. Date: May 8, 2025

(54) DISPLAY DEVICE

(71) Applicant: AUO Corporation, Hsinchu City (TW)

(72) Inventors: Ming-Lung Chen, Hsinchu City (TW); Kun-Cheng Tien, Hsinchu City (TW); Chien-Hung Kuo, Hsinchu City (TW); June Woo Lee, Hsinchu City (TW)

(73) Assignee: AUO Corporation, Hsinchu City (TW)

(21) Appl. No.: 18/827,836

(22) Filed: Sep. 8, 2024

(30) Foreign Application Priority Data
Nov. 8, 2023 (TW) 112143079

(51) Int. Cl. H01L 25/075; H01L 33/20

(52) U.S. Cl. CPC H01L 25/0753; H10H 20/819

(57) ABSTRACT

A display device includes a first pixel and a second pixel. The first pixel includes first light-emitting diodes. Each first light-emitting diode includes a first bottom semiconductor layer and a first top semiconductor layer stacked along a vertical direction. The second pixel includes second light-emitting diodes. Each second light-emitting diode includes a second bottom semiconductor layer and a second top semiconductor layer stacked along the vertical direction. In one of the first light-emitting diodes of the first pixel, a first mesa region is located in a first direction of a first overlap region, and in another of the first light-emitting diodes of the first pixel, the first mesa region is located in a second direction opposite to the first direction of the first overlap region. In each second light-emitting diode of the second pixel, a second mesa region is located in the second direction of a second overlap region.

### CROSS-REFERENCE TO RELATED APPLICATION

This application claims the priority benefit of Taiwan application serial no. 112143079, filed on Nov. 8, 2023. The entirety of the above-mentioned patent application is hereby incorporated by reference herein and made a part of this specification.

### BACKGROUND OF THE INVENTION

### Field of the Invention

The invention relates to a display device.

### Description of Related Art

Light-emitting diode (LED) technique is widely used in a variety of display devices including TVs, smartphones, automotive displays, and head-mounted display devices, etc., due to advantages thereof such as high contrast, excellent color performance, and excellent high resolution. Generally, an LED includes an N-type semiconductor layer and a P-type semiconductor layer stacked together. Two electrodes are respectively disposed on the N-type semiconductor layer and the P-type semiconductor layer to enable current to pass through the N-type semiconductor layer and the P-type semiconductor layer. Common LEDs include horizontal LEDs (or flip-chip LEDs) with two electrodes disposed at the same side and vertical LEDs with two electrodes disposed at different sides. Due to structural asymmetry, the brightness of horizontal LEDs is prone to change under different angles of view, thus causing display devices including horizontal LEDs to readily suffer from color distortion under different angles of view.

### SUMMARY OF THE INVENTION

The invention provides a display device that may alleviate the color distortion issue.

At least one embodiment of the invention provides a display device including a first pixel and a second pixel. The first pixel includes a plurality of first light-emitting diodes. Each of the first light-emitting diodes includes a first bottom semiconductor layer and a first top semiconductor layer stacked along a vertical direction, wherein a region in which the first bottom semiconductor layer is overlapped with the first top semiconductor layer in the vertical direction is defined as a first overlap region, and a region in which the first bottom semiconductor layer is not overlapped with the first top semiconductor layer in the vertical direction is defined as a first mesa region. The second pixel includes a plurality of second light-emitting diodes. Each of the second light-emitting diodes includes a second bottom semiconductor layer and a second top semiconductor layer stacked along the vertical direction, wherein a region in which the second bottom semiconductor layer is overlapped with the second top semiconductor layer in the vertical direction is defined as a second overlap region, and a region in which the second bottom semiconductor layer is not overlapped with the second top semiconductor layer in the vertical direction is defined as a second mesa region. In the first pixel, the first mesa region of one of the first light-emitting diodes is located in a first direction of the first overlap region, and the first mesa region of another of the first light-emitting diodes is located in a second direction opposite to the first direction of the first overlap region. In the second pixel, the second mesa region of each of the second light-emitting diodes is located in the second direction of the second overlap region.

### BRIEF DESCRIPTION OF THE DRAWINGS

FIG. 1 is a schematic cross-sectional view of a first pixel of a display device according to an embodiment of the invention.

FIG. 2 is a brightness curve diagram of different colors under different angles of view of a display device according to an embodiment of the invention.

FIG. 3 is a schematic cross-sectional view of a second pixel of a display device according to an embodiment of the invention.

FIG. 4 is a partial circuit diagram of a second pixel of a display device according to an embodiment of the invention.

FIG. 5 is a schematic perspective view of a display device according to an embodiment of the invention.

FIG. 6 is a schematic perspective view of a display device according to an embodiment of the invention.

FIG. 7 is a schematic perspective view of a display device according to an embodiment of the invention.

FIG. 8 is a schematic perspective view of a display device according to an embodiment of the invention.

FIG. 9 is a schematic cross-sectional view of a third pixel of a display device according to an embodiment of the invention.

FIG. 10 is a graph showing the relationship between angle of view and color shift value of display devices according to some comparative examples and an embodiment of the invention.

FIG. 11 is a schematic top view of some arrangement units of a first pixel and a second pixel according to the invention.

FIG. 12A to FIG. 12C are schematic top views of display devices according to some embodiments of the invention.

FIG. 13A to FIG. 13C are schematic top views of display devices according to some embodiments of the invention.

FIG. 14 is a schematic top view of some arrangement units of the first pixel and the second pixel according to the invention.

FIG. 15A to FIG. 15F are schematic top views of some arrangement units of the first pixel and the second pixel according to the invention.

### DESCRIPTION OF THE EMBODIMENTS

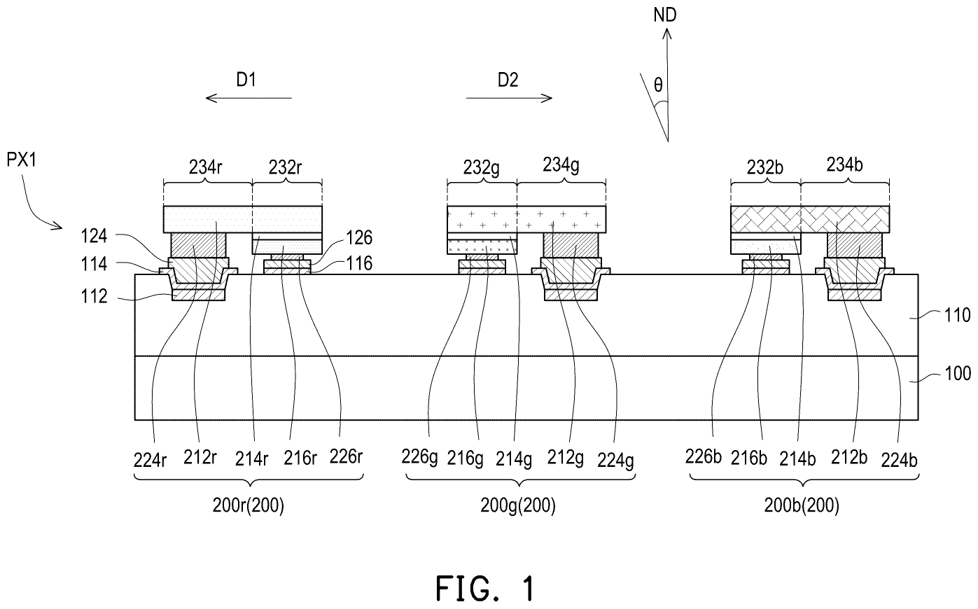

FIG. 1 is a schematic cross-sectional view of a first pixel PX1 of a display device according to an embodiment of the invention. Referring to FIG. 1, a display device includes a substrate 100, a circuit structure 110 disposed on the substrate 100, and a first pixel PX1 disposed on the circuit structure 110.

The substrate 100 is, for example, a rigid substrate, and a material thereof may be glass, quartz, organic polymer, or opaque/reflective material (such as conductive material, metal, wafer, ceramic, or other applicable materials), or other applicable materials. However, the invention is not limited thereto. In other embodiments, the substrate 100 may also be a flexible substrate or a stretchable substrate. For example, the material of the flexible substrate and the stretchable substrate includes polyimide (PI), polydimethylsiloxane (PDMS), polyethylene terephthalate (PET), polyethylene naphthalate (PEN), polyester (PES), polymethylmethacrylate (PMMA), polycarbonate (PC), polyurethane (PU), or other suitable materials. The circuit structure 110 includes, for example, a plurality of conductive layers and a plurality of insulating layers. FIG. 1 shows a conductive pattern 112, a plurality of first pads 114, and a plurality of second pads 116 in the circuit structure 110. In some embodiments, the circuit structure 110 also includes a plurality of active elements (not shown in FIG. 1) and/or a plurality of passive elements (not shown in FIG. 1), and the active elements (not shown in FIG. 1) may be thin-film transistors.

The first pixel PX1 includes a plurality of first light-emitting diodes 200. In the present embodiment, the first light-emitting diodes 200 include a first red light-emitting diode 200r, a first green light-emitting diode 200g, and a first blue light-emitting diode 200b.

The first red light-emitting diode 200r includes a first bottom semiconductor layer 212r and a first top semiconductor layer 216r stacked along a vertical direction ND. In some embodiments, there is a first light-emitting layer 214r between the first bottom semiconductor layer 212r and the first top semiconductor layer 216r. The region in which the first bottom semiconductor layer 212r is overlapped with the first top semiconductor layer 216r in the vertical direction ND is defined as a first overlap region 232r, and the region in which the first bottom semiconductor layer 212r is not overlapped with the first top semiconductor layer 216r in the vertical direction ND is defined as a first mesa region 234r. A first electrode 224r and a second electrode 226r are respectively in contact with the first bottom semiconductor layer 212r and the first top semiconductor layer 216r, and respectively overlapped with the first mesa region 234r and the first overlap region 232r. The first electrode 224r and the second electrode 226r are respectively bonded to the corresponding first pad 114 and the corresponding second pad 116 via a corresponding first bonding structure 124 and a corresponding second bonding structure 126. The first bonding structure 124 and the second bonding structure 126 include, for example, solder, conductive adhesive, or other suitable materials.

The first green light-emitting diode 200g includes a first bottom semiconductor layer 212g and a first top semiconductor layer 216g stacked along the vertical direction ND. In some embodiments, there is a first light-emitting layer 214g between the first bottom semiconductor layer 212g and the first top semiconductor layer 216g. The region in which the first bottom semiconductor layer 212g is overlapped with the first top semiconductor layer 216g in the vertical direction ND is defined as a first overlap region 232g, and the region in which the first bottom semiconductor layer 212g is not overlapped with the first top semiconductor layer 216g in the vertical direction ND is defined as a first mesa region 234g. A first electrode 224g and a second electrode 226g are respectively in contact with the first bottom semiconductor layer 212g and the first top semiconductor layer 216g, and respectively overlapped with the first mesa region 234g and the first overlap region 232g. The first electrode 224g and the second electrode 226g are respectively bonded to the corresponding first pad 114 and the corresponding second pad 116 via the corresponding first bonding structure 124 and the corresponding second bonding structure 126.

The first blue light-emitting diode 200b includes a first bottom semiconductor layer 212b and a first top semiconductor layer 216b stacked along the vertical direction ND. In some embodiments, there is a first light-emitting layer 214b between the first bottom semiconductor layer 212b and the first top semiconductor layer 216b. The region in which the first bottom semiconductor layer 212b is overlapped with the first top semiconductor layer 216b in the vertical direction ND is defined as a first overlap region 232b, and the region in which the first bottom semiconductor layer 212b is not overlapped with the first top semiconductor layer 216b in the vertical direction ND is defined as a first mesa region 234b. A first electrode 224b and a second electrode 226b are respectively in contact with the first bottom semiconductor layer 212b and the first top semiconductor layer 216b, and respectively overlapped with the first mesa region 234b and the first overlap region 232b. The first electrode 224b and the second electrode 226b are respectively bonded to the corresponding first pad 114 and the corresponding second pad 116 via the corresponding first bonding structure 124 and the corresponding second bonding structure 126.

In the first pixel PX1, the first mesa region 234r of one of the first light-emitting diodes 200 (for example, the first red light-emitting diode 200r) is located in a first direction D1 of the first overlap region 232r, and the first mesa region 234g, 234b of another of the first light-emitting diodes 200 (for example, the first green light-emitting diode 200g or the first blue light-emitting diode 200b) is located in a second direction D2 opposite to the first direction D1 of the first overlap region 232g, 232b.

In some embodiments, one of the first bottom semiconductor layer 212r and the first top semiconductor layer 216r of the first red light-emitting diode 200r includes a first P-type semiconductor, and the other includes a first N-type semiconductor. In some embodiments, one of the first bottom semiconductor layer 212g and the first top semiconductor layer 216g of the first green light-emitting diode 200g includes a second P-type semiconductor, and the other includes a second N-type semiconductor. In some embodiments, one of the first bottom semiconductor layer 212b and the first top semiconductor layer 216b of the first blue light-emitting diode 200b includes a third P-type semiconductor, and the other includes a third N-type semiconductor.

In some embodiments, the first bottom semiconductor layer 212r, the first top semiconductor layer 216g, and the first top semiconductor layer 216b have the same doping form (for example, all are N-type semiconductors or all are P-type semiconductors), and the first top semiconductor layer 216r, the first bottom semiconductor layer 212g, and the first bottom semiconductor layer 212b have another same doping form (for example, all are N-type semiconductors or all are P-type semiconductors).

In some embodiments, the first top semiconductor layer 216r, the first bottom semiconductor layer 212g, and the first bottom semiconductor layer 212b are electrically connected to a common signal, and the first bottom semiconductor layer 212r, the first top semiconductor layer 216g, and the first top semiconductor layer 216b are respectively electrically connected to different active elements, but the invention is not limited thereto. In other embodiments, the first bottom semiconductor layer 212r, the first top semiconductor layer 216g, and the first top semiconductor layer 216b are electrically connected to a common signal, and the first top semiconductor layer 216r, the first bottom semiconductor layer 212g, and the first bottom semiconductor layer 212b are respectively electrically connected to different active elements.

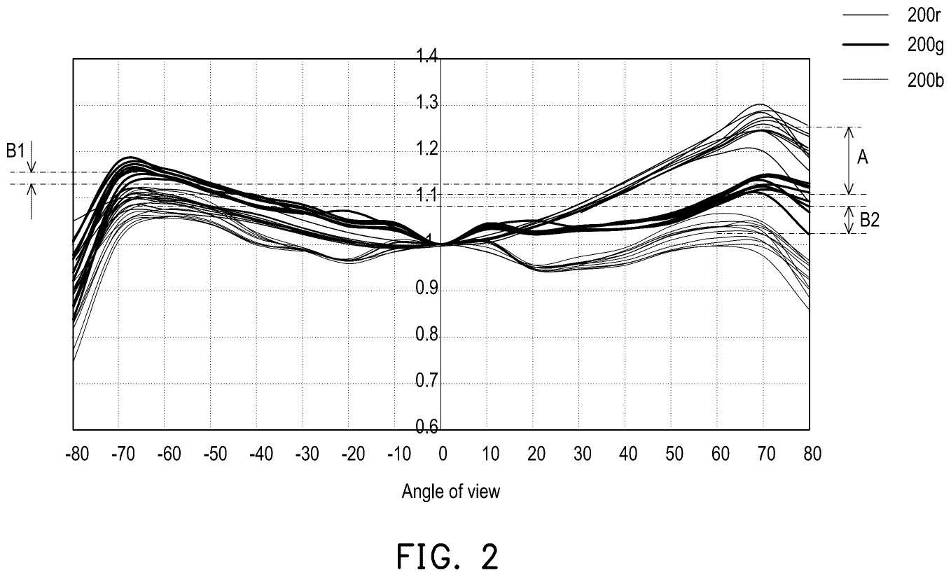

FIG. 2 is a brightness curve diagram of different colors under different angles of view of a display device according to an embodiment of the invention, wherein the horizontal axis is the angle of view (unit: degrees), and the vertical axis is the brightness ratio (unitless) obtained after the brightness is normalized. For example, the display device includes a display region formed by the first pixel PX1 of FIG. 1, an angle of view θ is changed parallel to the first direction D1, and the change in the brightness ratio is calculated by normalizing based on a brightness at an angle of view of 0 degrees (that is, positive angle of view). In FIG. 2, a plurality of tests are performed to obtain relatively accurate values. Therefore, in FIG. 2, each color has a plurality of data lines.

There is an average difference A between the brightness ratio peak at a negative angle of view and the brightness ratio peak at a positive angle of view of the first red light-emitting diode 200r of the first pixel PX1. There is an average difference B1 between the brightness ratio peak at a negative angle of view and the brightness ratio peak at a positive angle of view of the first green light-emitting diode 200r of the first pixel PX1. There is an average difference B2 between the brightness ratio peak at a negative angle of view and the brightness ratio peak at a positive angle of view of the first blue light-emitting diode 200b. In some embodiments, A is greater than B1 and B2. In some embodiments, B1 is approximately equal to B2.

It may be known from FIG. 2 that, the first red light-emitting diode 200r, the first green light-emitting diode 200r, and the first blue light-emitting diode 200b have different degrees of brightness changes under different angles of view θ. This is due to the fact that light-emitting diodes of different colors are produced using different processes, materials, and/or structures. Generally, from the angle of view in which the overlap region of the semiconductor layer of the light-emitting diode is tilted toward the mesa region of the bottom semiconductor layer, the light-emitting diode has higher brightness. Taking the first pixel PX1 of FIG. 1 as an example, the first red light-emitting diode 200r has a higher brightness ratio peak when the angle of view θ is greater than 0, and the first green light-emitting diode 200r and the first blue light-emitting diode 200b have a higher brightness ratio peak when the angle of view θ is less than 0. This is due to the fact that the position of the first mesa region 234r of the first red light-emitting diode 200r relative to the first overlap region 232r is different from the positions of the first mesa regions 234g, 234b of the first green light-emitting diode 200r and the first blue light-emitting diode 200b relative to the first overlap regions 232g, 232b.

In some embodiments, the brightness ratio peaks of the first red light-emitting diode 200r, the first green light-emitting diode 200g, and the first blue light-emitting diode 200b at a negative angle of view all appear at an angle of view between −50 degrees and −80 degrees, and the brightness ratio peaks of the first red light-emitting diode 200r, the first green light-emitting diode 200g, and the first blue light-emitting diode 200b at a positive angle of view all appear at an angle of view between 50 degrees and 80 degrees.

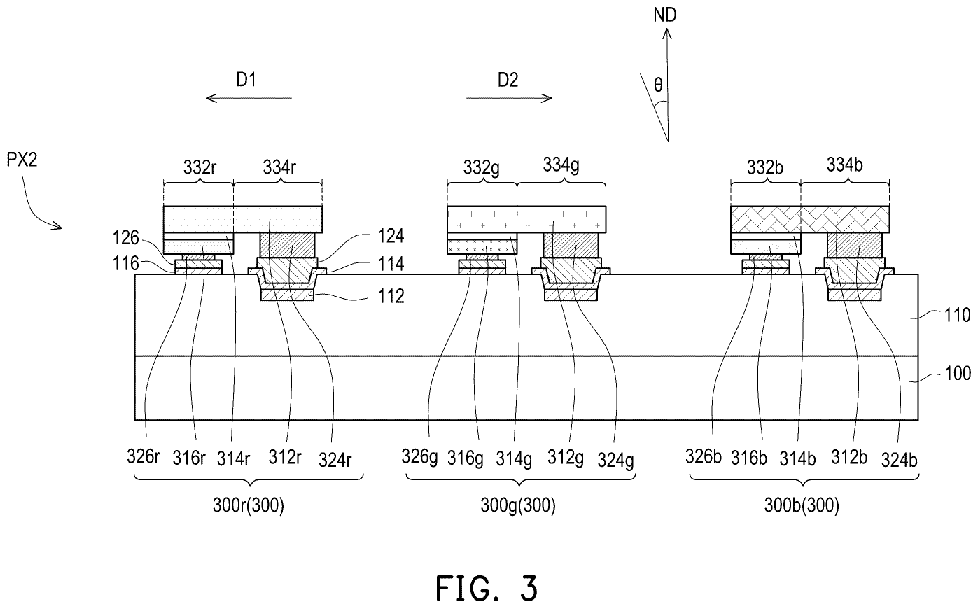

FIG. 3 is a schematic cross-sectional view of the second pixel PX2 of a display device according to an embodiment of the invention. For example, in order to alleviate the issue of inconsistent brightness changes between positive and negative angles of view shown in FIG. 2, the second pixel PX2 including a flipped red light-emitting diode (i.e., a second red light-emitting diode 300r) is provided.

The second pixel PX2 is disposed on the circuit structure 110. The second pixel PX2 includes a plurality of second light-emitting diodes 300. In the present embodiment, the second light-emitting diodes 300 include a second red light-emitting diode 300r, a second green light-emitting diode 300g, and a second blue light-emitting diode 300b.

The second red light-emitting diode 300r includes a second bottom semiconductor layer 312r and a second top semiconductor layer 316r stacked along the vertical direction ND. In some embodiments, there is a second light-emitting layer 314r between the second bottom semiconductor layer 312r and the second top semiconductor layer 316r. The region in which the second bottom semiconductor layer 312r is overlapped with the second top semiconductor layer 316r in the vertical direction ND is defined as a second overlap region 332r, and the region in which the second bottom semiconductor layer 312r is not overlapped with the second top semiconductor layer 316r in the vertical direction ND is defined as a second mesa region 334r. A first electrode 324r and a second electrode 326r are respectively in contact with the second bottom semiconductor layer 312r and the second top semiconductor layer 316r, and respectively overlapped with the second mesa region 334r and the second overlap region 332r. The first electrode 324r and the second electrode 326r are respectively bonded to the corresponding first pad 114 and the corresponding second pad 116 via the corresponding first bonding structure 124 and the corresponding second bonding structure 126.

The second green light-emitting diode 300g includes a second bottom semiconductor layer 312g and a second top semiconductor layer 316g stacked along the vertical direction ND. In some embodiments, there is a second light-emitting layer 314g between the second bottom semiconductor layer 312g and the second top semiconductor layer 316g. The region in which the second bottom semiconductor layer 312g is overlapped with the second top semiconductor layer 316g in the vertical direction ND is defined as a second overlap region 332g, and the region in which the second bottom semiconductor layer 312g is not overlapped with the second top semiconductor layer 316g in the vertical direction ND is defined as a second mesa region 334g. The first electrode 324g and the second electrode 326g are respectively in contact with the second bottom semiconductor layer 312g and the second top semiconductor layer 316g, and respectively overlapped with the second mesa region 334g and the second overlap region 332g. A first electrode 324g and a second electrode 326g are respectively bonded to the corresponding first pad 114 and the corresponding second pad 116 via the corresponding first bonding structure 124 and the corresponding second bonding structure 126.

The second blue light-emitting diode 300b includes a second bottom semiconductor layer 312b and a second top semiconductor layer 316b stacked along the vertical direction ND. In some embodiments, there is a second light-emitting layer 314b between the second bottom semiconductor layer 312b and the second top semiconductor layer 316b. The region in which the second bottom semiconductor layer 312b is overlapped with the second top semiconductor layer 316b in the vertical direction ND is defined as a second overlap region 332b, and the region in which the second bottom semiconductor layer 312b is not overlapped with the second top semiconductor layer 316b in the vertical direction ND is defined as a second mesa region 334b. A first electrode 324b and a second electrode 326b are respectively in contact with the second bottom semiconductor layer 312b and the second top semiconductor layer 316b, and respectively overlapped with the second mesa region 334b and the second overlap region 332b. The first electrode 324b and the second electrode 326b are respectively bonded to the corresponding first pad 114 and the corresponding second pad 116 via the corresponding first bonding structure 124 and the corresponding second bonding structure 126.

In the second pixel PX2, the second mesa regions 334r, 334g, and 334b of each of the second light-emitting diodes 300 (including the second red light-emitting diode 300r, the second green light-emitting diode 300g, and the second blue light-emitting diode 300b) are all located in the second direction D2 of the second overlap regions 332r, 332g, and 332b.

In some embodiments, the material of the first bottom semiconductor layer 212r and the material of the first top semiconductor layer 216r of the first red light-emitting diode 200r (please refer to FIG. 1) are respectively equivalent to the material of the second bottom semiconductor layer 312r and the material of the second top semiconductor layer 316r of the second red light-emitting diode 300r. In other words, one of the second bottom semiconductor layer 312r and the second top semiconductor layer 316r includes the first P-type semiconductor, and the other includes the first N-type semiconductor. In some embodiments, the material of the first bottom semiconductor layer 212g and the material of the first top semiconductor layer 216g of the first green light-emitting diode 200g (please refer to FIG. 1) are respectively equivalent to the material of the second bottom semiconductor layer 312g and the material of the second top semiconductor layer 316g of the second green light-emitting diode 300g. In other words, one of the second bottom semiconductor layer 312g and the second top semiconductor layer 316g includes the second P-type semiconductor, and the other includes the second N-type semiconductor. In some embodiments, the material of the first bottom semiconductor layer 212b and the material of the first top semiconductor layer 216b of the first blue light-emitting diode 200b (please refer to FIG. 1) are respectively equivalent to the material of the second bottom semiconductor layer 312b and the material of the second top semiconductor layer 316b of the second blue light-emitting diode 300b. In other words, one of the second bottom semiconductor layer 312b and the second top semiconductor layer 316b includes the third P-type semiconductor, and the other includes the third N-type semiconductor.

In some embodiments, the second bottom semiconductor layer 312r, the second top semiconductor layer 316g, and the second top semiconductor layer 316b have the same doping form (for example, all are N-type semiconductors or all are P-type semiconductors), and the second top semiconductor layer 316r, the second bottom semiconductor layer 312g, and the second bottom semiconductor layer 312b have another same doping form (for example, all are N-type semiconductors or all are P-type semiconductors).

In some embodiments, the second top semiconductor layer 316r, the second bottom semiconductor layer 312g, and the second bottom semiconductor layer 312b are electrically connected to a common signal, and the second bottom semiconductor layer 312r, the second top semiconductor layer 316g, and the second top semiconductor layer 316b are respectively electrically connected to different active elements, but the invention is not limited thereto. In other embodiments, the second bottom semiconductor layer 312r, the second top semiconductor layer 316g, and the second top semiconductor layer 316b are electrically connected to a common signal, and the second top semiconductor layer 316r, the second bottom semiconductor layer 312g, and the second bottom semiconductor layer 312b are respectively electrically connected to different active elements.

In some embodiments, by making the display device include the first pixel PX1 (please refer to FIG. 1) and the second pixel PX2 (please refer to FIG. 3), the issue of uneven positive and negative angles of view caused by the structural asymmetry of horizontal light-emitting diodes is alleviated.

In some embodiments, the quantity of the second pixel PX2 is greater than or equal to the quantity of the first pixel PX1. In some embodiments, the quantity of the second pixel PX2 and the quantity of the first pixel PX1 are approximately A:B (please refer to FIG. 2), wherein B is B1 or B2 in FIG. 2. In some embodiments, A:B is about 2:1, 3:2, 4:3, 5:4, 6:4, or other suitable values.

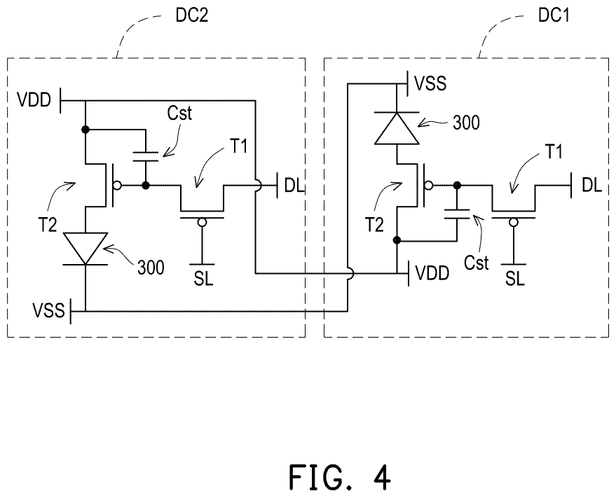

FIG. 4 is a partial circuit diagram of the second pixel PX2 of a display device according to an embodiment of the invention. In the present embodiment, a driving circuit DC1 and a driving circuit DC2 of each of the light-emitting diodes 300 each include one switching transistor T1, one driving transistor T2, and one storage capacitor Cst. The gate of the switching transistor T1 is electrically connected to a scan line SL, and the first source/drain is electrically connected to a data line DL. The gate of the driving transistor T2 is electrically connected to the second source/drain of the switching transistor T1, and the first source/drain of the driving transistor T2 is electrically connected to a first common signal line VDD. The storage capacitor Cst is electrically connected to the gate of the driving transistor T2 and the first source/drain of the driving transistor T2.

One of the electrodes (for example, the electrode electrically connected to the P-type semiconductor) of the light-emitting diodes 300 is electrically connected to the second source/drain of the driving transistor T2, and another electrode (for example, the electrode electrically connected to the N-type semiconductor) of the light-emitting diodes 300 is electrically connected to a second common signal line VSS.

Please refer to FIG. 3 and FIG. 4. For example, the second bottom semiconductor layer 312r, the second top semiconductor layer 316g, and the second top semiconductor layer 316b are all P-type semiconductors, and the first electrode 324r of the second red light-emitting diode 300r, the second electrode 326g of the second green light-emitting diode 300g, and the second electrode 326b of the second blue light-emitting diode 300b are respectively electrically connected to the second source/drain of the corresponding driving transistor T2. At the same time, the second top semiconductor layer 316r, the second bottom semiconductor layer 312g, and the second bottom semiconductor layer 312b are all N-type semiconductors, and the second electrode 326r of the second red light-emitting diode 300r, the first electrode 324g of the second green light-emitting diode 300g, and the first electrode 324b of the second blue light-emitting diode 300b are all electrically connected to the second common signal line VSS.

In the present embodiment, since the relative positions of the first electrode 324r and the second electrode 326r of the second red light-emitting diode 300r are different from (e.g., opposite to) the relative positions of the first electrode 324g and the second electrode 326g of the second green light-emitting diode 300g (or the first electrode 324b and the second electrode 326b of the second blue light-emitting diode 300b), the driving circuit DC1 corresponding to the second red light-emitting diode 300r and the driving circuit DC2 corresponding to the second green light-emitting diode 300g (or the second blue light-emitting diode 300b) have different layouts. For example, the driving transistor T2 may be reversed from left to right.

Although FIG. 4 takes as an example an architecture in which the driving circuit DC1 and the driving circuit DC2 each have two thin-film transistors and one capacitor (2T1C), the invention is not limited thereto. The driving circuit DC1 and the driving circuit DC2 may also each have a 1TIC architecture, a 3TIC architecture, a 3T2C architecture, a 4TIC architecture, a 4T2C architecture, a 5TIC architecture, a 5T2C architecture, a 6TIC architecture, a 6T2C architecture, a 7T2C architecture, or any possible architecture.

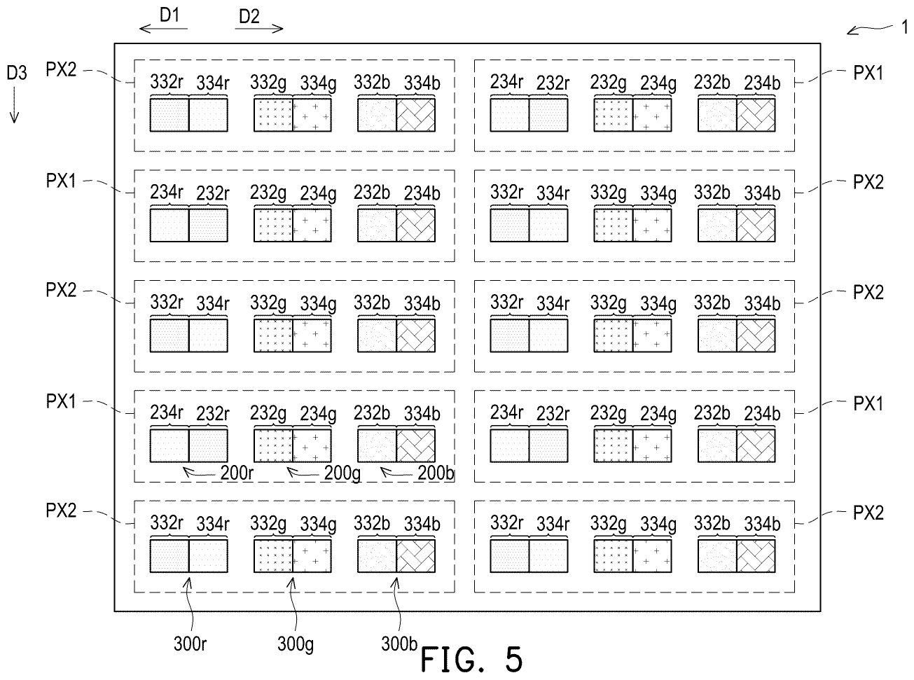

FIG. 5 is a schematic perspective view of a display device 1 viewed along the vertical direction ND (please refer to FIG. 1 and FIG. 3) according to an embodiment of the invention. The display device 1 includes a plurality of first pixels PX1 and a plurality of second pixels PX2. For the content of the first pixels PX1 and the second pixels PX2, please refer to FIG. 1, FIG. 3, and related descriptions.

Please refer to FIG. 5, the first pixels PX1 and the second pixels PX2 are arrayed on the circuit structure 110. In some embodiments, the first green light-emitting diodes 200g of the first pixels PX1 and the second green light-emitting diodes 300g of the second pixels PX2 have the same structure and direction. Therefore, the first green light-emitting diode 200g and the second green light-emitting diode 300g may be transferred onto the circuit structure 110 together in one mass transfer process. Similarly, the first blue light-emitting diodes 200b of the first pixels PX1 and the second blue light-emitting diodes 300b of the second pixels PX2 have the same structure and direction. Therefore, the first blue light-emitting diodes 200b and the second blue light-emitting diodes 300b may be transferred onto the circuit structure 110 together in one mass transfer process. The first green light-emitting diodes 200g and the second green light-emitting diodes 300g may be formed on the same growth substrate, and the first blue light-emitting diodes 200b and the second blue light-emitting diodes 300b may also be formed on the same growth substrate.

The first red light-emitting diodes 200r of the first pixels PX1 and the second red light-emitting diodes 300r of the second pixels PX2 have the same structure but have different directions. Therefore, the first red light-emitting diodes 200r and the second red light-emitting diodes 300r are transferred onto the circuit structure 110 in different mass transfer processes. The first red light-emitting diodes 200r and the second red light-emitting diodes 300r may be formed on the same growth substrate, but transferred using different transfer processes.

In the present embodiment, the arrangement direction of the first red light-emitting diodes 200r, the first green light-emitting diodes 200g, and the first blue light-emitting diodes 200b of the first pixels PX1 is parallel to the first direction D1 and the second direction D2. Similarly, the arrangement direction of the second red light-emitting diodes 300r, the second green light-emitting diodes 300g, and the second blue light-emitting diodes 300b of the second pixels PX2 is also parallel to the first direction D1 and the second direction D2.

In the present embodiment, in the first pixels PX1 and the second pixels PX2 adjacent in the first direction D1, the first red light-emitting diodes 200r, the first green light-emitting diodes 200g, and the first blue light-emitting diodes 200b are respectively aligned with the second red light-emitting diodes 300r, the second green light-emitting diodes 300g, and the second blue light-emitting diodes 300b in the first direction D1.

A third direction D3 is perpendicular to the first direction D1. In the present embodiment, in the first pixels PX1 and the second pixels PX2 adjacent in the third direction D3, the first red light-emitting diodes 200r, the first green light-emitting diodes 200g, and the first blue light-emitting diodes 200b are respectively aligned with the second red light-emitting diodes 300r, the second green light-emitting diodes 300g, and the second blue light-emitting diodes 300b in the third direction D3.

In the present embodiment, in the first pixels PX1 and the second pixels PX2 adjacent in the third direction D3, the first mesa regions 234r and the first overlap regions 232r of the first red light-emitting diodes 200r are respectively aligned with the second overlap regions 332r and the second mesa regions 334r of the second red light-emitting diodes 300r in the third direction D3.

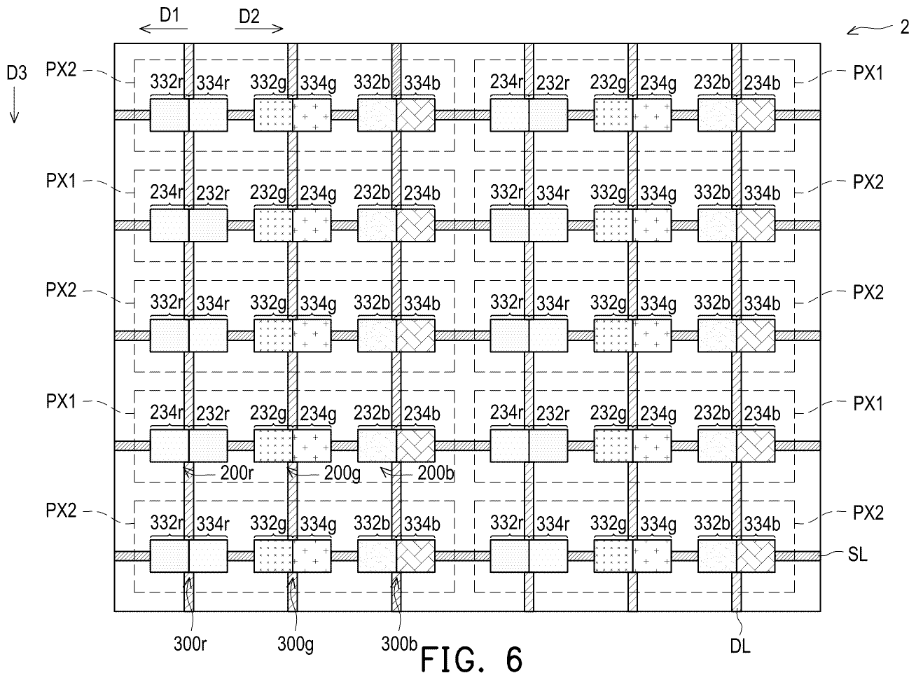

FIG. 6 is a schematic perspective view of a display device 2 according to an embodiment of the invention. It should be mentioned here that, the embodiment of FIG. 6 adopts the reference numerals of the embodiment of FIG. 5 and a portion of the contents thereof, wherein the same or similar numerals are used to represent the same or similar elements and descriptions of the same technical contents are omitted. For descriptions of the omitted portions, reference may be made to the above embodiments and are not described again here. The difference between FIG. 6 and FIG. 5 is that FIG. 6 also shows the scan lines SL and the data lines DL of the display device 2.

Referring to FIG. 6, the circuit structure 110 includes, for example, the scan lines SL and the data lines DL. In one first pixel PX1, the first red light-emitting diode 200r, the first green light-emitting diode 200g, and the first blue light-emitting diode 200b are electrically connected to the same scan line SL via the respective driving circuits thereof (please refer to FIG. 4), and are electrically connected to three different data lines DL. Similarly, in one second pixel PX2, the second red light-emitting diode 300r, the second green light-emitting diode 300g, and the second blue light-emitting diode 300b are electrically connected to the same scan line SL via the respective driving circuits thereof (please refer to FIG. 4), and are electrically connected to three different data lines DL.

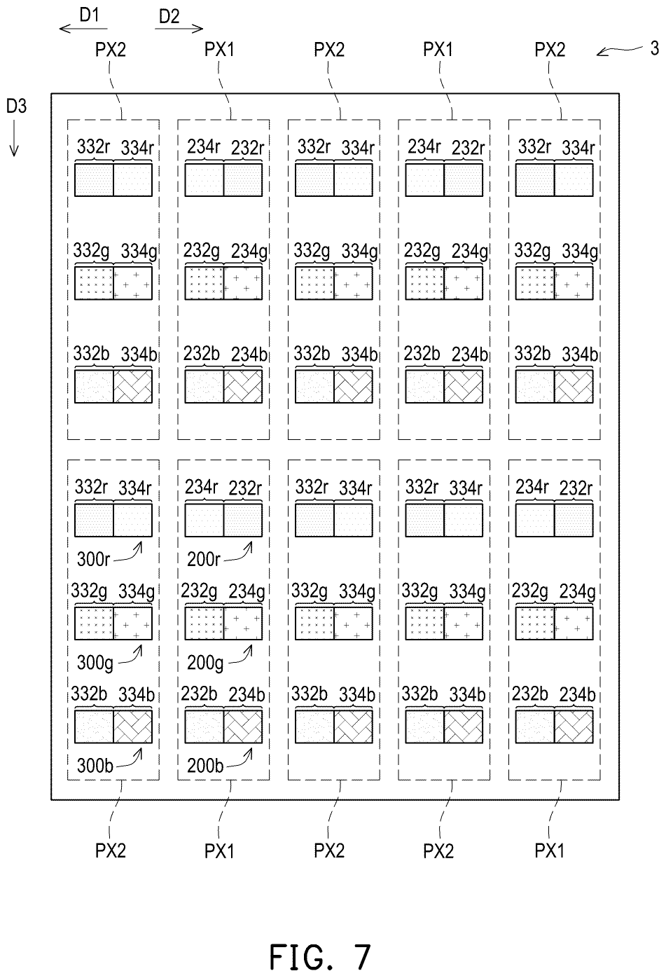

FIG. 7 is a schematic perspective view of a display device 3 according to an embodiment of the invention. It should be mentioned here that, the embodiment of FIG. 7 adopts the reference numerals of the embodiment of FIG. 5 and a portion of the contents thereof, wherein the same or similar numerals are used to represent the same or similar elements and descriptions of the same technical contents are omitted. For descriptions of the omitted portions, reference may be made to the above embodiments and are not described again here. The difference between the display device 3 of FIG. 7 and the display device 1 of FIG. 5 is: in the display device 3, the arrangement direction of the first red light-emitting diode 200r, the first green light-emitting diode 200g, and the first blue light-emitting diode 200b of the first pixel PX1 is perpendicular to the first direction D1 and the second direction D2. Similarly, the arrangement direction of the second red light-emitting diode 300r, the second green light-emitting diode 300g, and the second blue light-emitting diode 300b of the second pixel PX2 is also perpendicular to the first direction D1 and the second direction D2.

In the present embodiment, the first red light-emitting diode 200r, the first green light-emitting diode 200g, and the first blue light-emitting diode 200b are arranged along the third direction D3, and the second red light-emitting diode 300r, the second green light-emitting diode 300g, and the second blue light-emitting diode 300b are also arranged along the third direction D3.

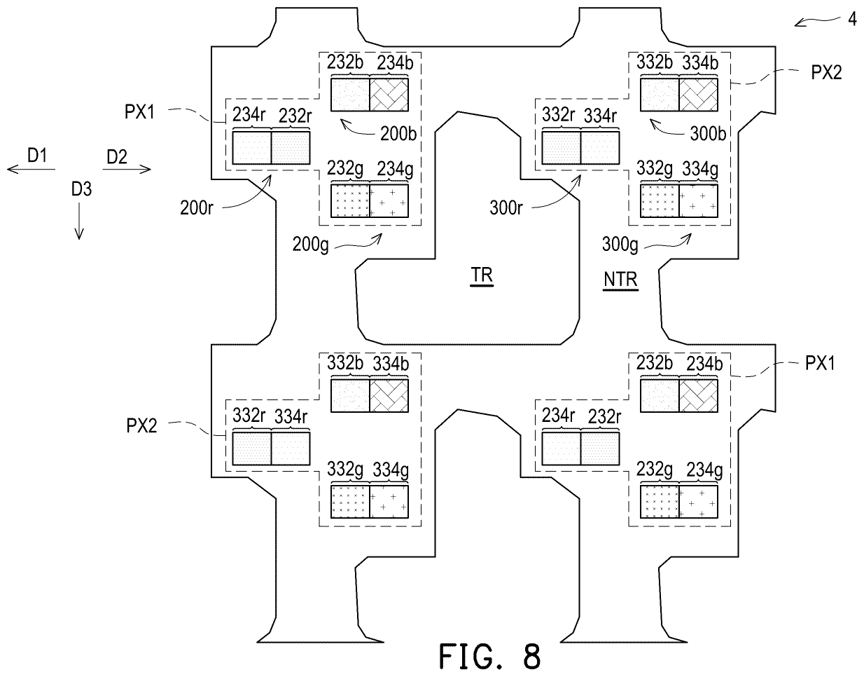

FIG. 8 is a schematic perspective view of a display device 4 according to an embodiment of the invention. It should be mentioned here that, the embodiment of FIG. 8 adopts the reference numerals of the embodiment of FIG. 5 and a portion of the contents thereof, wherein the same or similar numerals are used to represent the same or similar elements and descriptions of the same technical contents are omitted. For descriptions of the omitted portions, reference may be made to the above embodiments and are not described again here. The difference between the display device 4 of FIG. 8 and the display device 1 of FIG. 5 is that the display device 4 is a transmissive display device and includes a transmissive region TR and a non-transmissive region NTR. In the present embodiment, the first pixel PX1 and the second pixel PX2 are both disposed in the non-transmissive region NTR.

In the present embodiment, in the first pixel PX1 and the second pixel PX2 adjacent in the first direction D1, the first red light-emitting diode 200r, the first green light-emitting diode 200g, and the first blue light-emitting diode 200b are respectively aligned with the second red light-emitting diode 300r, the second green light-emitting diode 300g, and the second blue light-emitting diode 300b in the first direction D1.

The third direction D3 is perpendicular to the first direction D1. In the present embodiment, in the first pixel PX1 and the second pixel PX2 adjacent in the third direction D3, the first red light-emitting diode 200r, the first green light-emitting diode 200g, and the first blue light-emitting diode 200b are respectively aligned with the second red light-emitting diode 300r, the second green light-emitting diode 300g, and the second blue light-emitting diode 300b in the third direction D3.

In the present embodiment, in the first pixel PX1 and the second pixel PX2 adjacent in the third direction D3, the first mesa region 234r and the first overlap region 232r of the first red light-emitting diode 200r are respectively aligned with the second overlap region 332r and the second mesa region 334r of the second red light-emitting diode 300r in the third direction D3.

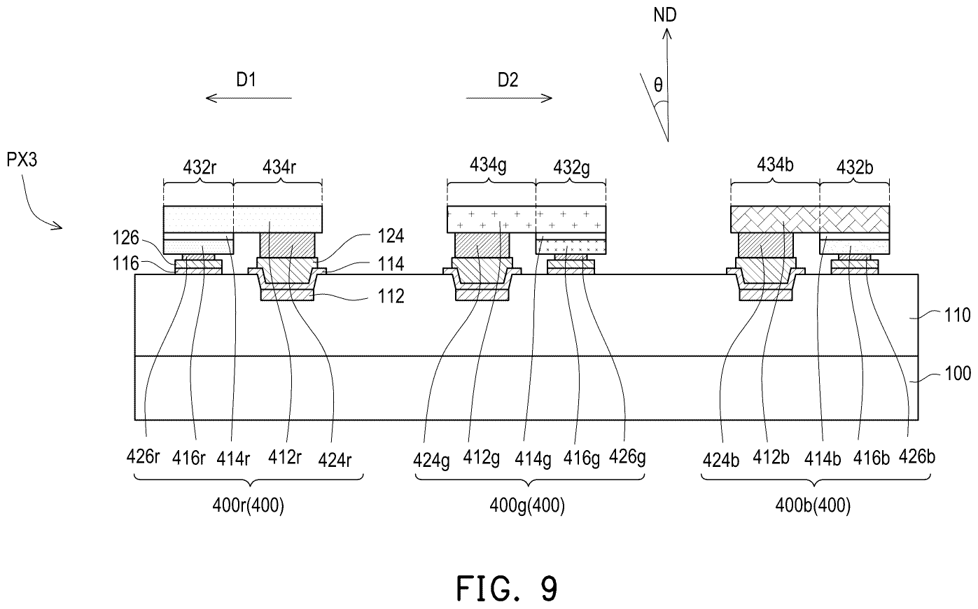

FIG. 9 is a schematic cross-sectional view of a third pixel PX3 of a display device according to an embodiment of the invention. The third pixel PX3 is similar to the first pixel PX1, except that the light-emitting diodes in the third pixel PX3 and the light-emitting diodes in the first pixel PX1 are opposite to each other.

The third pixel PX3 is disposed on the circuit structure 110. The third pixel PX3 includes a plurality of third light-emitting diodes 400. In the present embodiment, the third light-emitting diodes 400 include a third red light-emitting diode 400r, a third green light-emitting diode 400g, and a third blue light-emitting diode 400b.

The third red light-emitting diode 400r includes a third bottom semiconductor layer 412r and a third top semiconductor layer 416r stacked along the vertical direction ND. In some embodiments, there is a third light-emitting layer 414r between the third bottom semiconductor layer 412r and the third top semiconductor layer 416r. The region in which the third bottom semiconductor layer 412r is overlapped with the third top semiconductor layer 416r in the vertical direction ND is defined as a third overlap region 432r, and the region in which the third bottom semiconductor layer 412r is not overlapped with the third top semiconductor layer 416r in the vertical direction ND is defined as a third mesa region 434r. A first electrode 424r and a second electrode 426r are respectively in contact with the third bottom semiconductor layer 412r and the third top semiconductor layer 416r, and respectively overlapped with the third mesa region 434r and the third overlap region 432r. The third electrode 424r and the third electrode 426r are respectively bonded to the corresponding first pad 114 and the corresponding second pad 116 via the corresponding first bonding structure 124 and the corresponding second bonding structure 126.

The third green light-emitting diode 400g includes a third bottom semiconductor layer 412g and a third top semiconductor layer 416g stacked along the vertical direction ND. In some embodiments, there is a third light-emitting layer 414g between the third bottom semiconductor layer 412g and the third top semiconductor layer 416g. The region in which the third bottom semiconductor layer 412g is overlapped with the third top semiconductor layer 416g in the vertical direction ND is defined as a third overlap region 432g, and the region in which the third bottom semiconductor layer 412g is not overlapped with the third top semiconductor layer 416g in the vertical direction ND is defined as a third mesa region 434g. A first electrode 424g and a second electrode 426g are respectively in contact with the third bottom semiconductor layer 412g and the third top semiconductor layer 416g, and respectively overlapped with the third mesa region 434g and the third overlap region 432g. The first electrode 424g and the second electrode 426g are respectively bonded to the corresponding first pad 114 and the corresponding second pad 116 via the corresponding first bonding structure 124 and the corresponding second bonding structure 126.

The third blue light-emitting diode 400b includes a third bottom semiconductor layer 412b and a third top semiconductor layer 416b stacked along the vertical direction ND. In some embodiments, there is a third light-emitting layer 414b between the third bottom semiconductor layer 412b and the third top semiconductor layer 416b. The region in which the third bottom semiconductor layer 412b is overlapped with the third top semiconductor layer 416b in the vertical direction ND is defined as a third overlap region 432b, and the region in which the third bottom semiconductor layer 412b is not overlapped with the third top semiconductor layer 416b in the vertical direction ND is defined as a third mesa region 434b. A first electrode 424b and a second electrode 426b are respectively in contact with the third bottom semiconductor layer 412b and the third top semiconductor layer 416b, and respectively overlapped with the third mesa region 434b and the third overlap region 432b. The first electrode 424b and the second electrode 426b are respectively bonded to the corresponding first pad 114 and the corresponding second pad 116 via the corresponding first bonding structure 124 and the corresponding second bonding structure 126.

In the third pixel PX3, the third mesa region 434r of one of the third light-emitting diodes 400 (for example, the third red light-emitting diode 400r) is located in the second direction D2 of the third overlap region 432r, and the third mesa region 434g, 434b of another of the third light-emitting diodes 400 (for example, the third green light-emitting diode 400g or the third blue light-emitting diode 400b) is located in the first direction D1 of the third overlap region 432g, 432b.

In some embodiments, the material of the first bottom semiconductor layer 212r and the material of the first top semiconductor layer 216r of the first red light-emitting diode 200r (please refer to FIG. 1) are respectively equivalent to the material of the second bottom semiconductor layer 412r and the material of the second top semiconductor layer 416r of the third red light-emitting diode 400r. In some embodiments, the material of the first bottom semiconductor layer 212g and the material of the first top semiconductor layer 216g of the first green light-emitting diode 200g (please refer to FIG. 1) are respectively equivalent to the material of the third bottom semiconductor layer 412g and the material of the third top semiconductor layer 416g of the third green light-emitting diode 400g. In some embodiments, the material of the first bottom semiconductor layer 212b and the material of the first top semiconductor layer 216b of the first blue light-emitting diode 200b (please refer to FIG. 1) are respectively equivalent to the material of the third bottom semiconductor layer 412b and the material of the third top semiconductor layer 416b of the third blue light-emitting diode 400b.

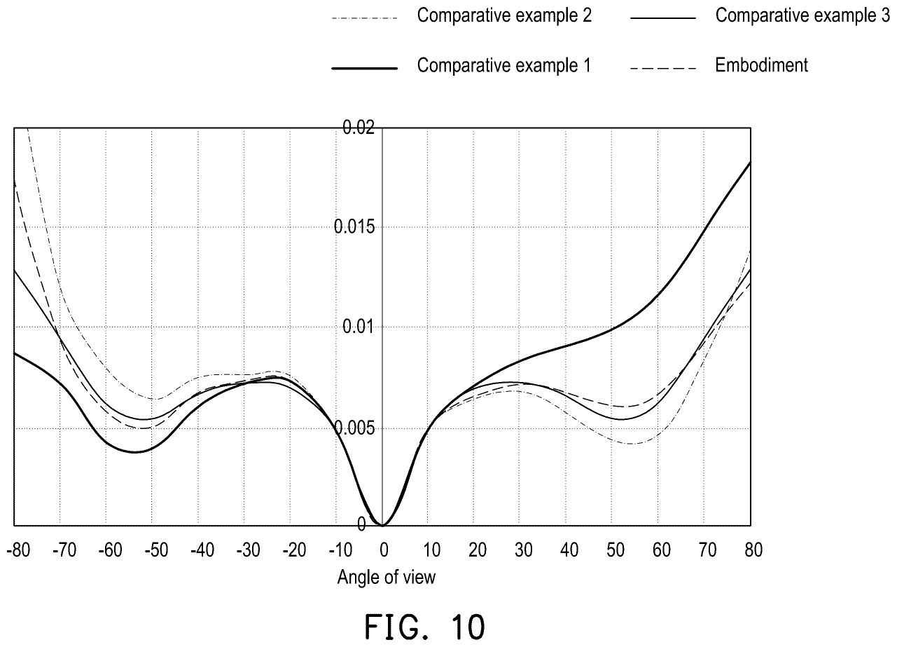

FIG. 10 is a graph showing the relationship between angle of view and color shift value of display devices according to some comparative examples and an embodiment of the invention. In FIG. 10, the horizontal axis is the angle of view (unit: degrees), and the vertical axis is the color shift value. The color shift value (delta u′v′) is the color shift change of u′v′ in CIE1976 (u′, v′) coordinates at different angles of views and is defined as delta v′ color shift value=v′ (different angles of view)-v′ (front view), delta u′ color shift value=u′ (different angles of view)-u′ (front view), color shift value (delta u′v′)=root ((delta v′) square+ (delta u′) square), and is a unitless indicator. The greater the color shift value, the more significant the color shift phenomenon is.

In Comparative example 1, each pixel of the display device is the first pixel PX1 as shown in FIG. 1. In Comparative example 2, each pixel of the display device is the second pixel PX2 as shown in FIG. 1. In Comparative example 3, the display region of the display device is formed by the first pixel PX1 shown in FIG. 1 and the third pixel PX3 shown in FIG. 9. In an embodiment, the display region of the display device is formed by the first pixel PX1 shown in FIG. 1 and the second pixel PX2 shown in FIG. 3, wherein the quantity of the first pixel PX1 and the quantity of the second pixel PX2 are, for example, 1:2.

It may be seen from FIG. 10 that by mixing the first pixel PX1 and the second pixel PX2, the color shift phenomenon may be suppressed and the color shift value of the positive angle of view and the color shift value of the negative angle of view may be more symmetrical.

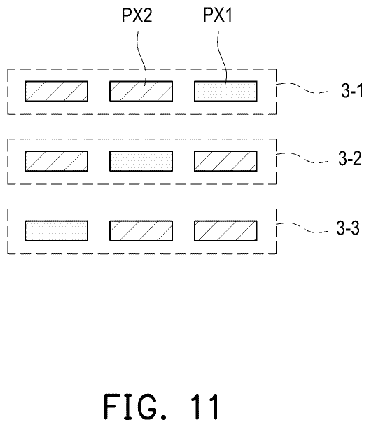

In some embodiments, the first pixel PX1 of FIG. 1 and the second pixel PX2 of FIG. 3 are arranged into a plurality of arrangement units in an arrangement direction parallel to the first direction D1, wherein the total quantity of the first pixel PX1 and the second pixel PX2 in each of the arrangement units is the same and is 3 to 10. In the same display device, the quantity of the first pixel PX1 of each of the arrangement units is the same as each other, and the quantity of the second pixel PX2 of each of the arrangement units is also the same as each other. In some embodiments, the quantity of the second pixel PX2 in each of the arrangement units is greater than the quantity of the first pixel PX1. FIG. 11 is a schematic top view of some arrangement units 3-1 to 3-3 of the first pixel PX1 and the second pixel PX2 according to the invention. In the arrangement units 3-1 to 3-3, the total quantity of the first pixel PX1 and the second pixel PX2 is 3, including two second pixels PX2 and one first pixel PX1.

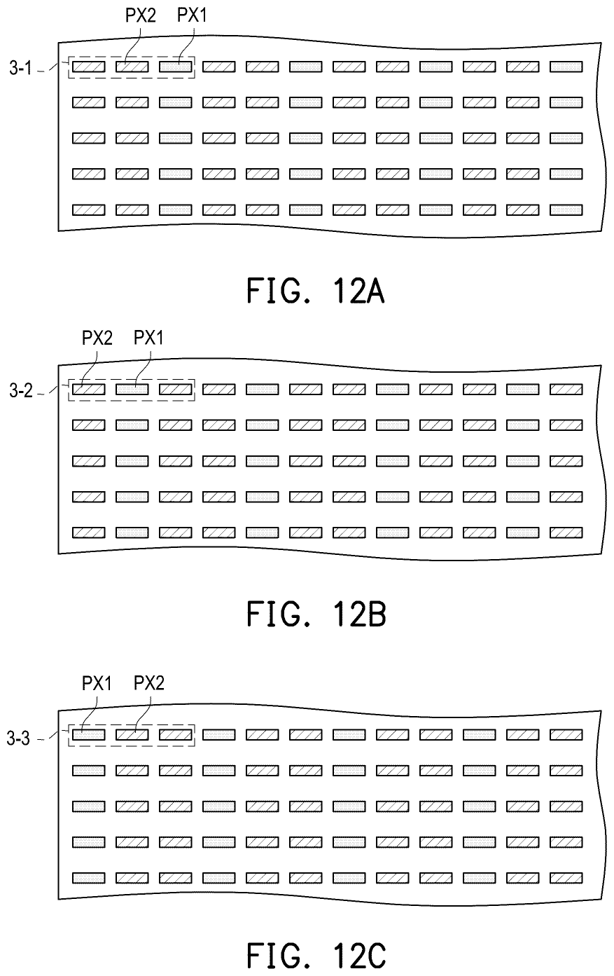

FIG. 12A to FIG. 12C are schematic top views of display devices according to some embodiments of the invention. In FIG. 12A, the display region of the display device is formed by the arrangement unit 3-1 in FIG. 11 arranged repeatedly. In FIG. 12B, the display region of the display device is formed by the arrangement unit 3-2 in FIG. 11 arranged repeatedly. In FIG. 12C, the display region of the display device is formed by the arrangement unit 3-3 in FIG. 11 arranged repeatedly.

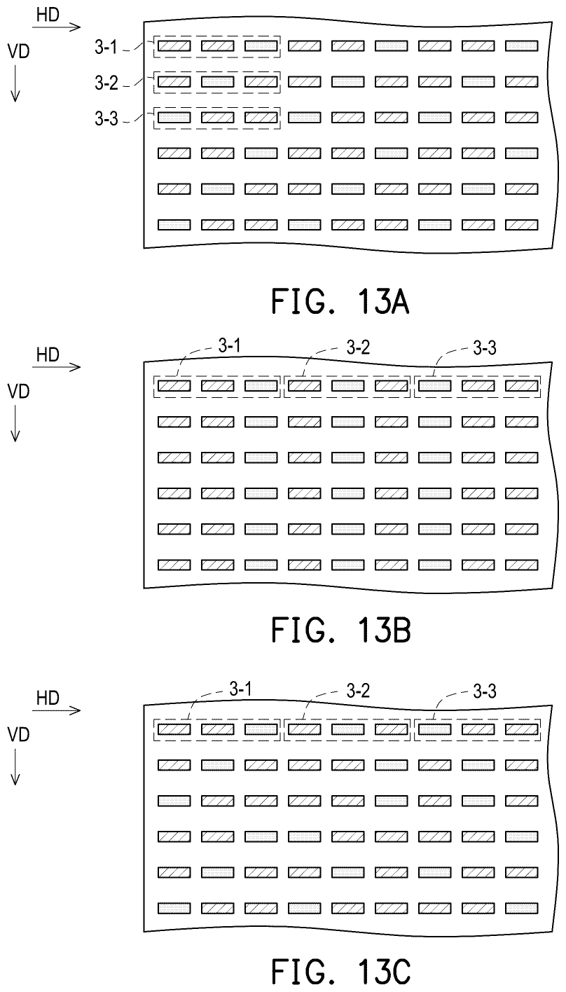

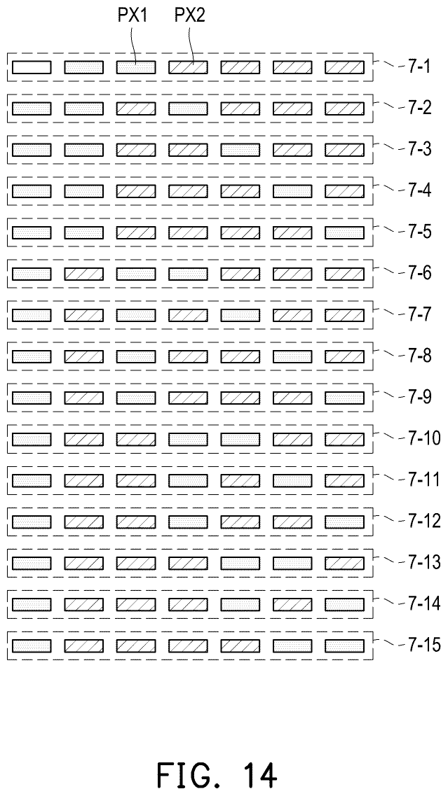

FIG. 13A to FIG. 13C are schematic top views of display devices according to some embodiments of the invention. The display regions of the display devices of FIG. 13A to FIG. 13C are all formed by the arrangement units 3-1 to 3-3 mixed together. In FIG. 13A, mixed (such as randomly mixed or periodically mixed) arrangement unit 3-1, arrangement unit 3-2, and arrangement unit 3-3 are provided in the vertical direction VD, and in the horizontal direction HD, the same arrangement unit is arranged repeatedly. In FIG. 13B, mixed (such as randomly mixed or periodically mixed) arrangement unit 3-1, arrangement unit 3-2, and arrangement unit 3-3 are provided in the horizontal direction HD, and in the vertical direction VD, the same arrangement unit is arranged repeatedly. In FIG. 13C, mixed (for example, randomly mixed or periodically mixed) arrangement unit 3-1, arrangement unit 3-2, and arrangement unit 3-3 are provided in the horizontal direction HD, and mixed (for example, randomly mixed or periodically mixed) arrangement unit 3-1, arrangement unit 3-2, and arrangement unit 3-3 are also provided in the vertical direction VD. By making the display device include the arrangement unit 3-1, the arrangement unit 3-2, and the arrangement unit 3-3 arranged in a mixed manner, the issue of stripes in the image displayed by the display device may be avoided.

FIG. 14 is a schematic top view of some arrangement units 7-1 to 7-15 of the first pixel PX1 and the second pixel PX2 according to the invention. In the arrangement units 7-1 to 7-15, the total quantity of the first pixel PX1 and the second pixel PX2 is 7, including four second pixels PX2 and three first pixels PX1. By arranging two or more of the arrangement units 7-1 to 7-15 in a mixed manner, stripe issue may be avoided in the image displayed by the display device. The arrangement units 7-1 to 7-15 may be arranged in a mixed manner (for example, random mixing or periodic mixing) in the horizontal direction and/or the vertical direction.

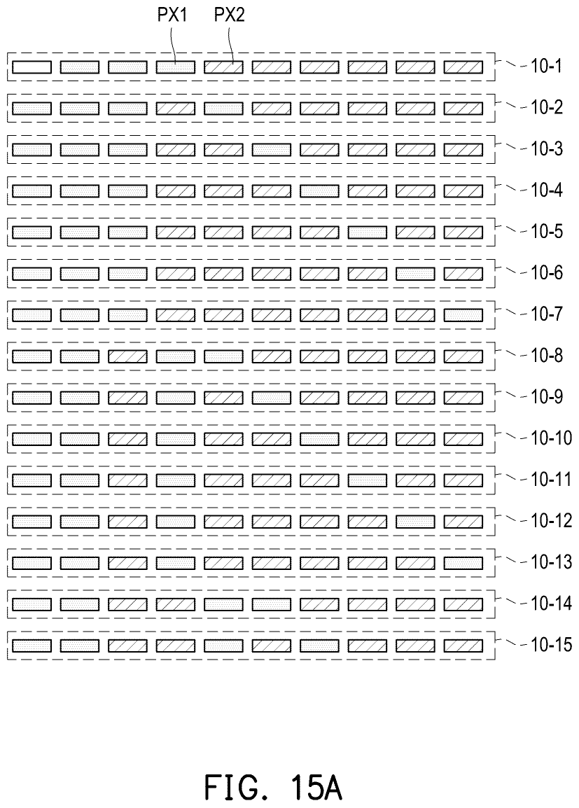

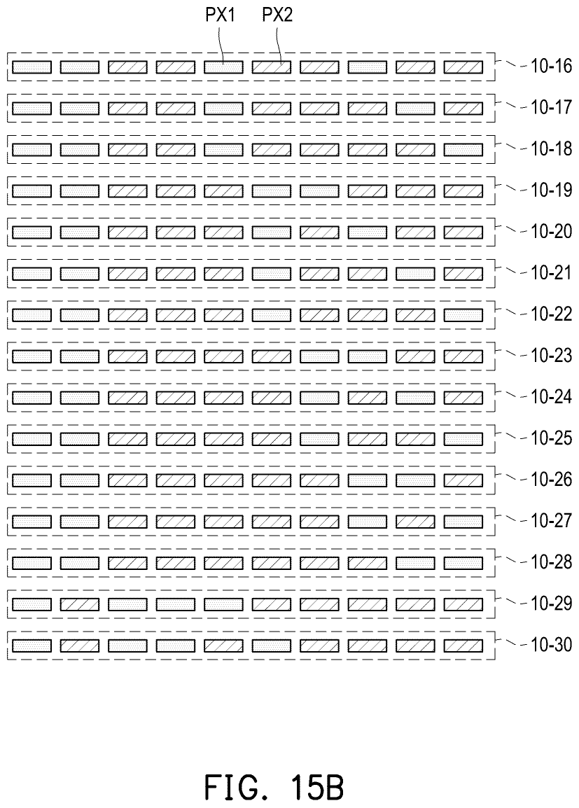

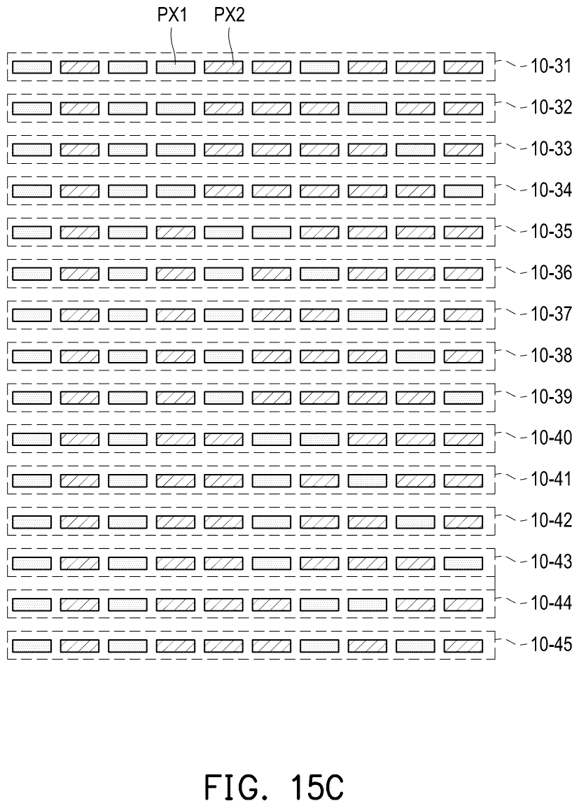

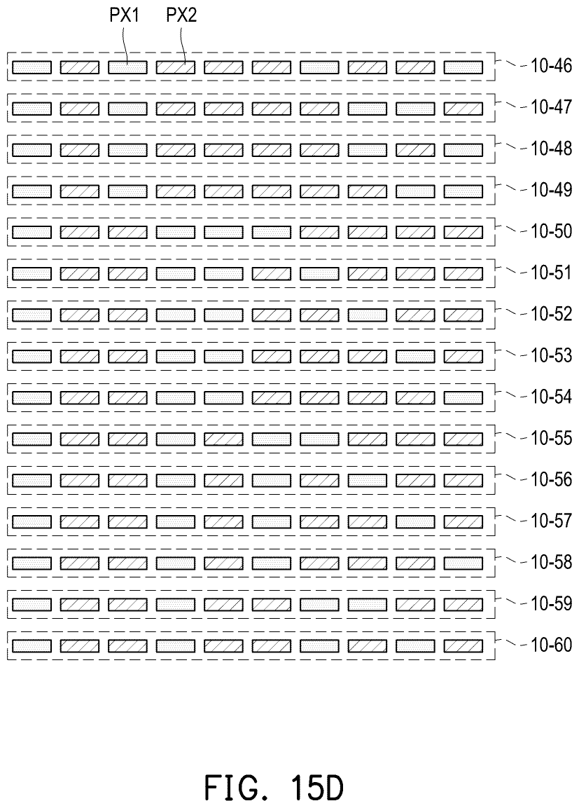

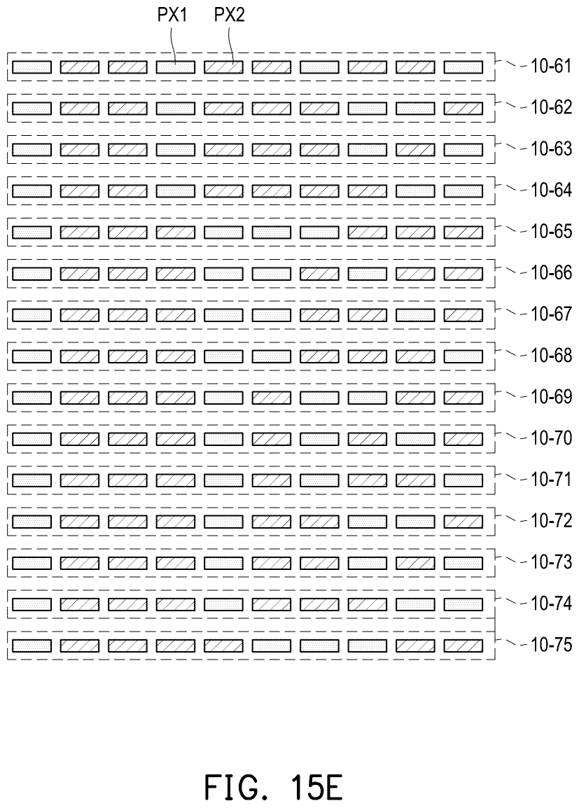

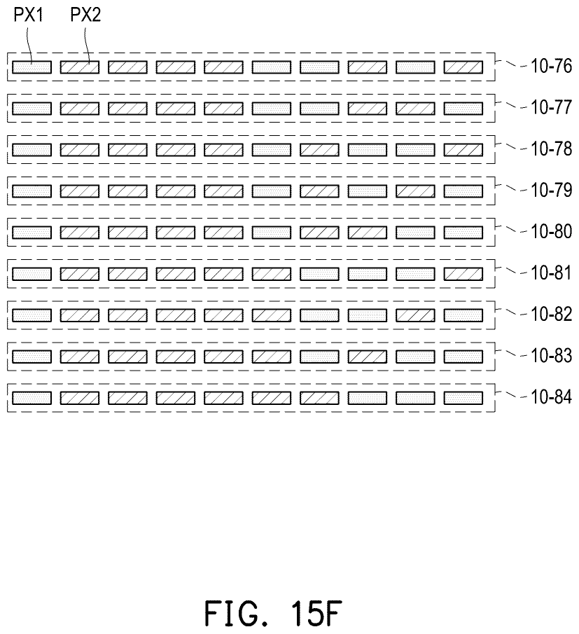

FIG. 15A to FIG. 15F are schematic top views of some arrangement units 10-1 to 10-84 of the first pixel PX1 and the second pixel PX2 according to the invention. In the arrangement units 10-1 to 10-84, the total quantity of the first pixels PX1 and the second pixels PX2 is 10, including six second pixels PX2 and four first pixels PX1. By arranging two or more of the arrangement units 10-1 to 10-84 in a mixed manner, the issue of stripes may be avoided in the image displayed by the display device. The arrangement units 10-1 to 10-84 may be arranged in a mixed manner (for example, random mixing or periodic mixing) in the horizontal direction and/or the vertical direction.

What is claimed is:

1. A display device, comprising:
a first pixel, comprising
a plurality of first light-emitting diodes, wherein each of the first light-emitting diodes comprises a first bottom semiconductor layer and a first top semiconductor layer stacked along a vertical direction, a region in which the first bottom semiconductor layer is overlapped with the first top semiconductor layer in the vertical direction is defined as a first overlap region, and a region in which the first bottom semiconductor layer is not overlapped with the first top semiconductor layer in the vertical direction is defined as a first mesa region; and
a second pixel, comprising
a plurality of second light-emitting diodes, wherein each of the second light-emitting diodes comprises a second bottom semiconductor layer and a second top semiconductor layer stacked along a vertical direction, a region in which the second bottom semiconductor layer is overlapped with the second top semiconductor layer in the vertical direction is defined as a second overlap region, and a region in which the second bottom semiconductor layer is not overlapped with the second top semiconductor layer in the vertical direction is defined as a second mesa region; wherein
in the first pixel, the first mesa region of one of the first light-emitting diodes is located in a first direction of the first overlap region, and the first mesa region of another of the first light-emitting diodes is located in a second direction opposite to the first direction of the first overlap region; and
in the second pixel, the second mesa region of each of the second light-emitting diodes is located in the second direction of the second overlap region.

2. The display device of claim 1, wherein a material of the first bottom semiconductor layer of the one of the first light-emitting diodes comprises a first P-type semiconductor, a material of the first top semiconductor layer of the another of the first light-emitting diodes comprises a second P-type semiconductor, a material of the first top semiconductor layer of the one of the first light-emitting diodes comprises a first N-type semiconductor, and a material of the first bottom semiconductor layer of the another of the first light-emitting diodes comprises a second N-type semiconductor.

3. The display device of claim 2, wherein a material of the second bottom semiconductor layer of one of the second light-emitting diodes comprises the first P-type semiconductor, a material of the second top semiconductor layer of another of the second light-emitting diodes comprises the second P-type semiconductor, a material of the second top semiconductor layer of the one of the second light-emitting diodes comprises the first N-type semiconductor, and a material of the second bottom semiconductor layer of the another of the second light-emitting diodes comprises the second N-type semiconductor.

4. The display device of claim 1, wherein one of the first light-emitting diodes is a first red light-emitting diode, the another one of the first light-emitting diodes is a first green light-emitting diode or a first blue light-emitting diode, and the second light-emitting diodes in the second pixel comprise a second red light-emitting diode, a second green light-emitting diode, and a second blue light-emitting diode.

5. The display device of claim 4, comprising a plurality of first pixels and a plurality of second pixels, wherein the one of the first light-emitting diodes of each of the first pixels is a first red light-emitting diode, the another of the first light-emitting diodes of each of the first pixels is a first green light-emitting diode, an angle of view parallel to the first direction is changed and a change in a brightness ratio is calculated by normalizing based on a brightness at an angle of view of 0 degrees, there is an average difference A between a brightness ratio peak at a negative angle of view and a brightness ratio peak at a positive angle of view of the first red light-emitting diodes of the first pixels, and there is an average difference B between a brightness ratio peak at a negative angle of view and a brightness ratio peak at a positive angle of view of the first green light-emitting diodes of the first pixels, wherein A is greater than B.

6. The display device of claim 5, wherein a quantity of the second pixels and a quantity of the first pixels are approximately A: B.

7. The display device of claim 5, wherein the brightness ratio peak of the first red light-emitting diodes at the negative angle of view and the brightness ratio peak of the first green light-emitting diodes at the negative angle of view appear at an angle of view between −50 degrees and −80 degrees, and the brightness ratio peak of the first red light-emitting diodes at the positive angle of view and the brightness ratio peak of the first green light-emitting diodes at the positive angle of view appear at an angle of view between 50 degrees and 80 degrees.

8. The display device of claim 1, comprising a plurality of first pixels and a plurality of second pixels, wherein a quantity of the second pixels is greater than or equal to a quantity of the first pixels.

9. The display device of claim 1, comprising a plurality of first pixels and a plurality of second pixels, wherein the first pixels and the second pixels are arranged into a plurality of arrangement units in an arrangement direction parallel to the first direction, a total quantity of the first pixels and the second pixels in each of the arrangement units is the same and is 3 to 10, a quantity of the second pixels of each of the arrangement units is the same as each other, and the quantity of the second pixels in each of the arrangement units is greater than a quantity of the first pixels.

10. The display device of claim 1, wherein the one of the first light-emitting diodes and one of the second light-emitting diodes are aligned with each other in a third direction perpendicular to the first direction, and the one of the first light-emitting diodes and the one of the second light-emitting diodes comprise light-emitting diodes of a same color.

11. The display device of claim 1, wherein the one of the first light-emitting diodes and one of the second light-emitting diodes are aligned with each other in the first direction, and the one of the first light-emitting diodes and the one of the second light-emitting diodes comprise light-emitting diodes of a same color.
